(19) United States
(12) Patent Application Publication
(10) Pub. No.: US 2026/0291459 A1
(43) Pub. Date: Sep. 24, 2026

(54) Electromagnetic Interference Shield

(71) Applicant: Apple Inc., Cupertino, CA (US)

(72) Inventors: Zhongning Liu, San Diego, CA (US); Amr Ibrahim, Belmont, MA (US); Zhang Jin, San Diego, CA (US); Yi Zhao, San Jose, CA (US); Mikhail Shirokov, Munich (DE)

(21) Appl. No.: 19/088,956

(22) Filed: Mar. 24, 2025

(51) Int. Cl. H03H 1/00; H03H 7/01

(52) U.S. Cl. CPC H03H 1/0007; H03H 7/0115; H03H 2001/0085

(57) ABSTRACT

This disclosure is directed to electromagnetic interference (EMI) shields of circuitry with electromagnetic sensitive components. The circuitry may include electromagnetic sensitive components and EMI shields. The EMI shields may include multiple components to attenuate EMI signals and reduce undesired EMI and/or interactions between the electromagnetic sensitive components. The EMI shields may include a shield layer, auxiliary trace and bumps, and/or guard rings. The shield layer may include a conductive layer overlaid on the on the electromagnetic sensitive components. The auxiliary trace and auxiliary bumps may form an enclosed conductive loop with the shield layer between two components (e.g., electromagnetic sensitive components) of the circuitry. The conductive loop may attenuate EMI signals between the electromagnetic sensitive components by generating magnetic fields in an opposite direction compared to at least a portion of the EMI signals.

### BACKGROUND

The present disclosure relates generally to shielding in electronic devices including electromagnetic sensitive components.

Electronic devices may include electromagnetic sensitive components such as inductors, among other things. In some cases, electromagnetic sensitive components may emit undesired electromagnetic interference (EMI) signals. Undesirable EMI signals, however, could interfere with the operation of the electromagnetic sensitive components in an electronic device.

### SUMMARY

This disclosure is generally directed to electromagnetic interference (EMI) shields of circuitry including electromagnetic sensitive components. The circuitry may include a first electromagnetic sensitive component, a second electromagnetic sensitive component, and the EMI shields, among other things. A horizontal plane may correspond to any plane or combination of planes at any possible angle on which the first electromagnetic sensitive component and the second electromagnetic sensitive component are laid out. Vertical planes may correspond to any plane or combination of planes that are perpendicular to the horizontal plane. Oriented on the horizontal plane, the first electromagnetic sensitive component and the second electromagnetic sensitive component may each emit EMI signals (e.g., magnetic fields) horizontally, vertically, and/or in other directions between the horizontal and vertical planes. The EMI shields may include multiple components to attenuate the EMI signals and reduce undesired EMI and/or interactions between the first electromagnetic sensitive component and the second electromagnetic sensitive component.

The EMI shields may include a shield layer, auxiliary trace and bumps, and/or guard rings. The shield layer may include a conductive layer overlaid on the on the horizontal plane including the first electromagnetic sensitive component and the second electromagnetic sensitive component. For example, the shield layer may be disposed on a second horizontal plane parallel to (e.g., disposed above or below) the horizontal plane including the first electromagnetic sensitive component and the second electromagnetic sensitive component. In some cases, the shield layer may be coupled to a ground voltage of the circuitry and/or may be virtually grounded. The shield layer may attenuate (e.g., absorb or block at least a portion of) vertically emitted EMI signals of the first electromagnetic sensitive component and the second electromagnetic sensitive component.

The auxiliary trace and auxiliary bumps may form a vertical conductive loop (e.g., a conductive loop, an enclosed conductive loop) with the shield layer. The auxiliary trace may be disposed horizontally perpendicular (e.g., nearly horizontally perpendicular) to and in between the first electromagnetic sensitive component and the second electromagnetic sensitive component on the horizontal plane. For example, the auxiliary trace may be grounded and/or virtually grounded. Moreover, the auxiliary bumps may couple the sides (e.g., ends) of the auxiliary trace to the overlaid shield layer disposed over or under the first electromagnetic sensitive component and the second electromagnetic sensitive component. As such, the auxiliary trace and auxiliary bumps may form a vertical conductive loop through the shield layer.

The vertical conductive loop may be formed on a vertical plane (e.g., nearly vertical plane) between the auxiliary trace and the auxiliary bumps. The vertical conductive loop may attenuate (e.g., lower an amplitude of) EMI signals between the first electromagnetic sensitive component and the second electromagnetic sensitive component. For example, EMI signals passing through an area of the vertical conductive loop may induce a current flow (e.g., eddy currents) on the vertical conductive loop. In turn, the induced currents may generate a magnetic field in opposite (e.g., nearly opposite) direction of the EMI signals, attenuating the EMI signals between the first electromagnetic sensitive component and the second electromagnetic sensitive component.

In some cases, the vertical conductive loop may reduce undesired EMI and/or interactions between the first electromagnetic sensitive component and the second electromagnetic sensitive component. In some embodiments, the first electromagnetic sensitive component may be disposed in closer proximity to the second electromagnetic sensitive component on the horizontal (e.g., nearly horizontal) plane of the circuitry based on the improved EMI shielding. As such, the circuitry including the first electromagnetic sensitive component and the second electromagnetic sensitive component may occupy a reduced area and/or have an improved EMI shielding. Moreover, components, chips, integrated circuits, systems on a chip, and so on including the circuitry may occupy a reduced area and/or have an improved EMI shielding.

In some embodiments, the EMI shields of the circuitry may also include a first guard ring and a second guard ring disposed on the on the horizontal plane. Each guard ring may include a closed-loop conductor (e.g., trace) having a circular and/or polygonal shape. The first guard ring may be disposed around and in proximity of a perimeter of the first electromagnetic sensitive component on the horizontal plane. Moreover, the second guard ring may be disposed around and in proximity of a perimeter of the second electromagnetic sensitive component on the horizontal plane. In some cases, the first guard ring and/or the second guard ring may be grounded and/or virtually grounded. As such, the first guard ring may attenuate (e.g., absorb at least a portion of) horizontally emitted EMI signals of the first electromagnetic sensitive component. Moreover, the second guard ring may attenuate (e.g., absorb at least a portion of) horizontally emitted EMI signals of the second electromagnetic sensitive component.

### BRIEF DESCRIPTION OF THE DRAWINGS

Various aspects of this disclosure may be better understood upon reading the following detailed description and upon reference to the drawings described below in which like numerals refer to like parts.

FIG. 1 is a block diagram of an electronic device including circuitry having electromagnetic interference (EMI) shields, according to embodiments of the present disclosure;

FIG. 2 is a front view of a handheld device representing an example of the electronic device of FIG. 1, according to embodiments of the present disclosure;

FIG. 3 is a front view of another handheld device representing another example of the electronic device of FIG. 1, according to embodiments of the present disclosure;

FIG. 4 is a perspective view of a notebook computer representing an example of the electronic device of FIG. 1, according to embodiments of the present disclosure;

FIG. 5 illustrates front and side views of a wearable electronic device representing another example of the electronic device of FIG. 1, according to embodiments of the present disclosure;

FIG. 6 illustrates a layout of the circuitry of FIGS. 1-5 including a first electromagnetic sensitive component disposed in proximity of a second electromagnetic sensitive component, according to embodiments of the present disclosure;

FIG. 7 illustrates a layout of the circuitry of FIG. 6 including the EMI shields, according to embodiments of the present disclosure;

FIG. 8A is a perspective view of the layout of the circuitry of FIG. 7 illustrating a vertical conductive loop formed by the EMI shields, according to embodiments of the present disclosure;

FIG. 8B is a perspective view of the layout of the circuitry of FIG. 8A illustrating induced currents on the vertical conductive loop generating magnetic fields that attenuate undesired electromagnetic emissions passing through the vertical conductive loop, according to embodiments of the present disclosure;

FIG. 9 is a block diagram of a package including the circuitry of FIGS. 6-8, according to embodiments of the present disclosure; and

FIG. 10 is a block diagram of an example implementation of the circuitry shown in FIGS. 6-9 in example filtering circuitry electronic devices of FIGS. 1-5, according to embodiments of the present disclosure.

### DETAILED DESCRIPTION OF SPECIFIC EMBODIMENTS

When introducing elements of various embodiments of the present disclosure, the articles “a,” “an,” and “the” are intended to mean that there are one or more of the elements. The terms “including” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. Furthermore, the particular features, structures, or characteristics may be combined in any suitable manner in one or more embodiments. Use of the terms “approximately,” “near,” “about,” “close to,” and/or “substantially” should be understood to mean including close to a target (e.g., design, value, amount), such as within a margin of any suitable or contemplatable error (e.g., within 0.1% of a target, within 1% of a target, within 5% of a target, within 10% of a target, within 25% of a target, and so on). Moreover, it should be understood that any exact values, numbers, measurements, and so on, provided herein, are contemplated to include approximations (e.g., within a margin of suitable or contemplatable error) of the exact values, numbers, measurements, and so on. Additionally, the term “set” may include one or more. That is, a set may include a unitary set of one member or a set may include multiple members. Furthermore, the term “continuous” may correspond to an activity that occurs without interruption or a consecutive repetition with a relatively short time period therebetween. Furthermore, the phrase A “based on” B is intended to mean that A is at least partially based on B. Moreover, the term “or” is intended to be inclusive (e.g., logical OR) and not exclusive (e.g., logical XOR). In other words, the phrase A “or” B is intended to mean A, B, or both A and B.

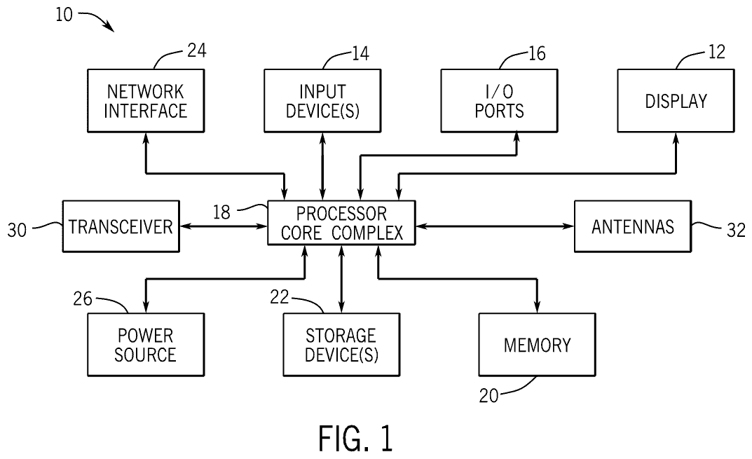

FIG. 1 is a block diagram of an electronic device 10, according to embodiments of the present disclosure. As is described in more detail below, the electronic device 10 may be any suitable electronic device, such as a computer, a mobile phone, a portable media device, a tablet, a television, a virtual reality headset, a wearable device such as a watch, a vehicle dashboard, or the like. Thus, it should be noted that FIG. 1 is merely one example of a particular implementation and is intended to illustrate the types of components that may be present in an electronic device 10.

The electronic device 10 may include an electronic display 12, one or more input devices 14, one or more input/output (I/O) ports 16, a processor core complex 18 having one or more processing circuitry(s) or processing circuitry cores, local memory 20, a main memory storage device 22, a network interface 24, a power supply 26 (e.g., power source), transceiver 30, and one or more antennas 32. The various components described in FIG. 1 may include hardware elements (e.g., circuitry), software elements (e.g., a tangible, non-transitory computer readable medium storing executable instructions), or a combination of both hardware and software elements. It should be noted that the various depicted components may be combined into fewer components or separated into additional components. For example, the local memory 20 and the main memory storage device 22 may be included in a single component.

The processor core complex 18 is operably coupled with local memory 20 and the main memory storage device 22. Thus, the processor core complex 18 may execute instructions stored in local memory 20 and/or the main memory storage device 22 to perform operations, such as generating or transmitting control signals to one or more components of the electronic device 10. As such, the processor core complex 18 may include one or more processors, one or more general purpose microprocessors, one or more application specific integrated circuits (ASICs), one or more programmable logic devices (PLDs) such as field programmable gate arrays (FPGAs), or any combination thereof. In some embodiments, a system on a chip (SoC) may include the processor core complex 18, among other things.

In addition to program instructions, the local memory 20 or the main memory storage device 22 may store data to be processed by the processor core complex 18. Thus, the local memory 20 and/or the main memory storage device 22 may include one or more tangible, non-transitory, computer readable media. For example, the local memory 20 may include random access memory (RAM) and the main memory storage device 22 may include read-only memory (ROM), rewritable non-volatile memory such as flash memory, hard drives, optical discs, or the like.

The network interface 24 may communicate data with another electronic device or a network. For example, the network interface 24 (e.g., a radio frequency system) may enable the electronic device 10 to communicatively couple to a personal area network (PAN), such as a Bluetooth network, a local area network (LAN), such as an 802.11x Wi-Fi network, or a wide area network (WAN), such as a 4G, Long-Term Evolution (LTE), or 5G cellular network.

The power supply 26 may provide electrical power to the various components of the electronic device 10. For example, the power supply 26 may provide the electrical power to the electronic display 12, the input devices 14, the I/O ports 16, the processor core complex 18, the local memory 20, the main memory storage device 22, the network interface 24, the power supply 26, the transceiver 30, or a combination thereof, among other things. The power supply 26 may include any suitable source of energy, such as a rechargeable lithium polymer (Li-poly) battery or an alternating current (AC) power converter.

The transceiver 30 may include transmitters and receivers coupled via communication buses to transmit and receive data. In some embodiments, the transceiver 30 may include circuitry for data communication using any version of a serializer and deserializer (SerDes) interface, a peripheral component interconnect express (PCIe) interface, or any other viable interfacing protocol, such as various communication standards. It should be appreciated that the transceiver 30 may include and/or utilize any viable circuitry to facilitate data communication between multiple circuits, components, chips, integrated circuits (ICs), and so on. For example, the transceiver 30 may be coupled to a first chip and a second chip to provide a chip-to-chip (C2C) interface. Moreover, it should be appreciated that the primary circuit and the secondary circuit of the transceiver 30 may communicate via a wired link (e.g., a bus) or a wireless link. For example, the transceiver 30 may use any viable communication protocol, such as Wi-Fi, 4G LTE, or 5G NR, among other possibilities, to establish and communicate using the wireless link.

The I/O ports 16 may enable the electronic device 10 to interface with other electronic devices. For example, when a portable storage device is connected, the I/O port 16 may enable the processor core complex 18 to communicate data with the portable storage device. The input devices 14 may enable user interaction with the electronic device 10, for example, by receiving user inputs via a button, a keyboard, a mouse, a trackpad, or the like. The input device 14 may include touch-sensing components in the electronic display 12. The touch sensing components may receive user inputs by detecting occurrence or position of an object touching the surface of the electronic display 12.

The electronic device 10 may include circuitry including multiple electromagnetic sensitive components laid out (e.g., disposed) in relative proximity of each other. The electronic display 12, the input devices 14, the I/O ports 16, the processor core complex 18, the local memory 20, the main memory storage device 22, the network interface 24, the power supply 26, the transceiver 30, and/or circuitry coupled to one or more antennas 32, or any combination thereof, may include one or more electromagnetic sensitive components. In some embodiments, one or more electromagnetic sensitive components of two or more different such components of the electronic device 10 may be disposed in relative proximity of each other. In alternative or additional embodiments, one such component of the electronic device 10 may include multiple electromagnetic sensitive components disposed in relative proximity of each other. The electronic device 10 may include electromagnetic interference (EMI) shields to reduce interference between the electromagnetic sensitive components of one or multiple components disposed in relative proximity of each other. Accordingly, components, chips, ICs, ASICs, SoCs, and so on of the electronic device 10 including the electromagnetic sensitive components may occupy a reduced area and/or have an improved EMI shielding.

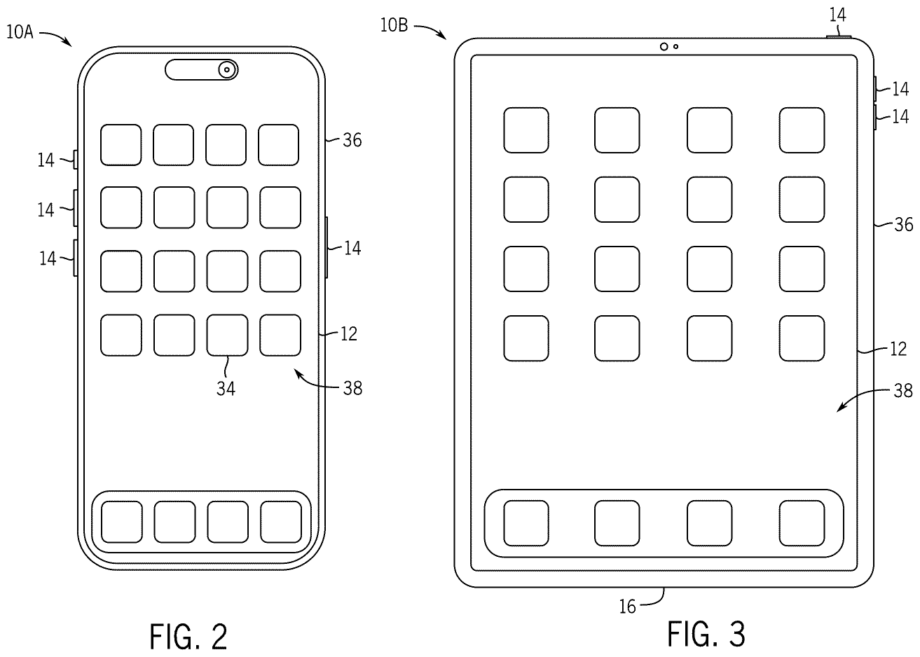

The electronic display 12 may include driver circuitry (e.g., display driver circuitry) and/or a display panel. The electronic device 10 may also have the one or more antennas 32 electrically coupled to the processor core complex 18. The electronic device 10 may be any suitable electronic device. To help illustrate, an example of the electronic device 10, a handheld device 10A, is shown in FIG. 2. The handheld device 10A may be a portable phone, a media player, a personal data organizer, a handheld game platform, or the like. For illustrative purposes, the handheld device 10A may be a smart phone, such as an IPHONE® model available from Apple Inc.

The handheld device 10A includes an enclosure 36 (e.g., housing). The enclosure 36 may protect interior components from physical damage or shield them from electromagnetic interference, such as by surrounding the electronic display 12. The electronic display 12 may display a graphical user interface (GUI) 38 having an array of icons. When an icon 34 is selected either by an input device 14 or a touch-sensing component of the electronic display 12, an application program may launch.

The input devices 14 may be accessed through openings in the enclosure 36. The input devices 14 may enable a user to interact with the handheld device 10A. For example, the input devices 14 may enable the user to activate or deactivate the handheld device 10A, navigate a user interface to a home screen, navigate a user interface to a user configurable application screen, activate a voice-recognition feature, provide volume control, or toggle between vibrate and ring modes.

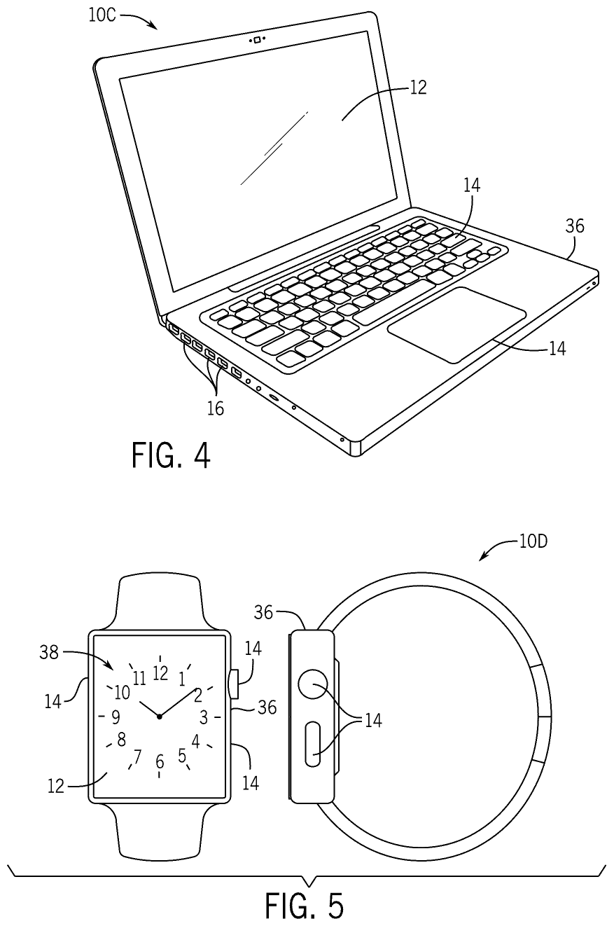

Another example of a suitable electronic device 10, specifically a tablet device 10B, is shown in FIG. 3. The tablet device 10B may be an IPAD® model available from Apple Inc. A further example of a suitable electronic device 10, specifically a computer 10C, is shown in FIG. 4. For illustrative purposes, the computer 10C may be a MACBOOK® or IMAC® model available from Apple Inc. Another example of a suitable electronic device 10, specifically a watch 10D, is shown in FIG. 5. For illustrative purposes, the watch 10D may be an APPLE WATCH® model available from Apple Inc. As depicted, the tablet device 10B, the computer 10C, and the watch 10D each also includes an electronic display 12, input devices 14, I/O ports 16, and an enclosure 36. The electronic display 12 may display a GUI 38.

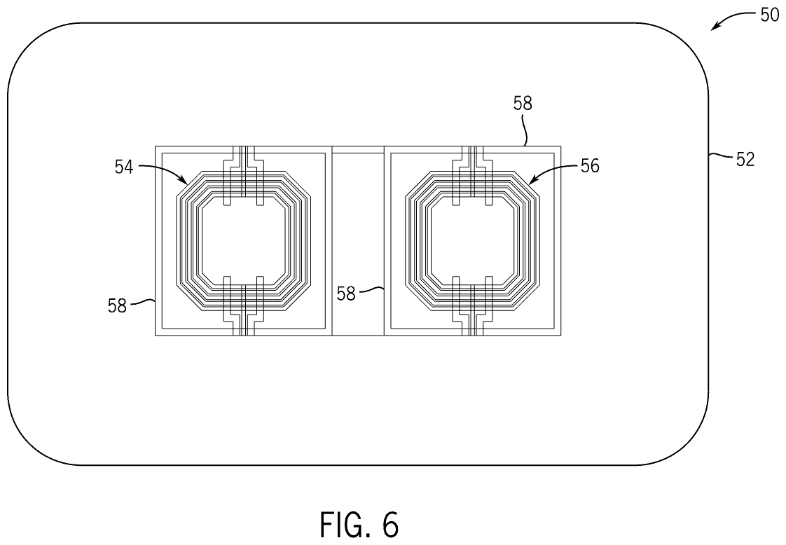

FIG. 6 illustrates a layout of circuitry 50 including a first electromagnetic sensitive component 54 disposed in proximity of a second electromagnetic sensitive component 56, according to embodiments of the present disclosure. The electronic devices 10 may include the circuitry 50 disposed on a first circuit layer 52. For example, the first circuit layer 52 may correspond to one or multiple layers of a printed circuit board on which the first electromagnetic sensitive component 54 and the second electromagnetic sensitive component 56 are disposed.

The first circuit layer 52 may be disposed on or oriented on a first horizontal plane. The first horizontal plane may correspond to any plane or any combination of planes at any possible angle on which the electromagnetic sensitive components 54 and 56 are laid out. Oriented on the first horizontal plane, the electromagnetic sensitive components 54 and 56 may each emit EMI signals (e.g., magnetic fields) horizontally, vertically, and/or in other directions between the first horizontal plane and various vertical planes. A vertical plane may correspond to any plane or combination of planes that are perpendicular to the first horizontal plane.

In some embodiments, the electromagnetic sensitive components 54 and 56 may each include inductive components such as an inductor or an antenna, among other possibilities. The inductive components may have any viable shape or form such as circular and polygonal, may have any viable number of turns and/or windings, and may be disposed in any viable fashion on the first circuit layer 52. In one non-limiting example, an inductor-capacitor (LC) filter of the electronic device 10 may include the circuitry 50. The LC filter may include a band-pass filter, a band-stop filter (e.g., a notch filter), a high-pass filter, or a low-pass filter. Alternatively or additionally, the first electromagnetic sensitive component 54 and/or the second electromagnetic sensitive component 56 may include any other viable component or any combination of components. For example, the first electromagnetic sensitive component 54 and/or the second electromagnetic sensitive component 56 may include any viable circuits, components, chips, ICs, SoCs, and so on.

A first (e.g., positive) terminal of the electromagnetic sensitive components 54 and 56 may each couple to or be coupled to other circuit components to receive input signals. For example, any viable circuit component of the electronic device 10, including but not limited to mixers and/or amplifiers, among other things, may couple to or be coupled to the first terminal of the first electromagnetic sensitive component 54 and/or the second electromagnetic sensitive component 56. A second (e.g., negative) terminal of the electromagnetic sensitive components 54 and 56 may each couple to or be coupled to other circuit components. For example, the second terminals may be grounded and/or virtually grounded.

In the depicted embodiment, the second terminal of the electromagnetic sensitive components 54 and 56 may be coupled to ground traces 58. For example, the ground traces 58 may couple to or may be coupled to ground traces or terminals (e.g., analog ground traces or terminals) of the electronic device 10. The ground traces 58 may be disposed around and in relative proximity of (e.g., non-overlapping with) a perimeter of the electromagnetic sensitive components 54 and 56 on the first horizontal plane. Moreover, the ground traces 58 may fully or partially enclose the electromagnetic sensitive components 54 and 56. The ground traces 58 may have any viable circular and/or polygonal shape.

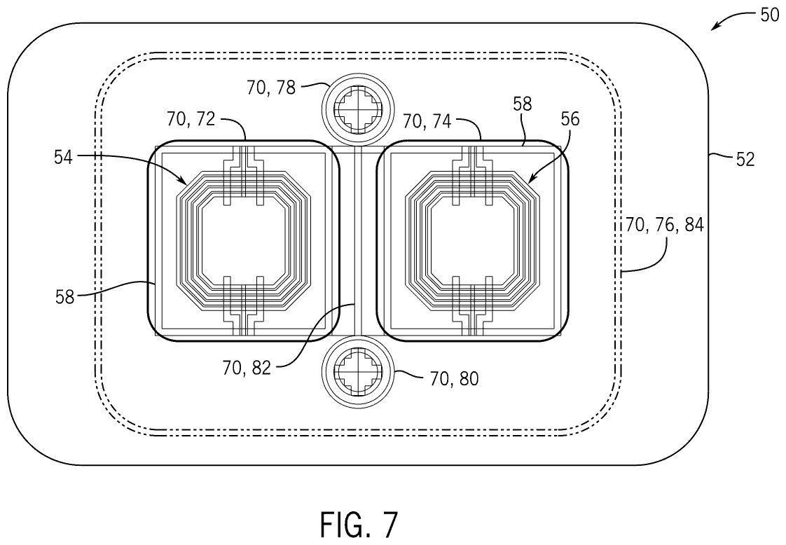

FIG. 7 illustrates a layout of the circuitry 50 of FIG. 6 including the EMI shields 70, according to embodiments of the present disclosure. The EMI shields 70 may include a first guard ring 72, a second guard ring 74, a shield layer 76, a first bump 78 (e.g., a first auxiliary bump), a second bump 80 (e.g., a second auxiliary bump), and an auxiliary trace 82. The shield layer 76 may include a conductive material disposed on a second circuit layer 84 of the circuitry 50 at least partially overlaid on the first circuit layer 52. For example, the second circuit layer 84 may correspond to one or multiple layers of the printed circuit board on which the circuitry 50 is disposed. The second circuit layer 84 may be disposed on a second horizontal plane. The second horizontal plane may correspond to any plane or any combination of planes at any possible angle that is parallel (e.g., exactly parallel, nearly parallel) or slightly parallel (e.g., within 5°, within 10°, within 20°, within 30°, within 45°) with the first horizontal plane.

In the depicted embodiment, a transparent view of the shield layer 76 overlaid on (e.g., above or below) the electromagnetic sensitive components 54 and 56 is shown. The shield layer 76 may have an area including (e.g., covering, surrounding, overlaid on) at least the first electromagnetic sensitive component 54, the second electromagnetic sensitive component 56, an area between the electromagnetic sensitive components 54 and 56 including the auxiliary trace 82, and the first bump 78 and the second bump 80. As such, the shield layer 76 may be overlaid on (e.g., above or below) and surround the first electromagnetic sensitive component 54, the second electromagnetic sensitive component 56, the first bump 78, the second bump 80, and the auxiliary trace 82. The shield layer 76 may attenuate (e.g., absorb at least a portion of) EMI signals (e.g., vertically emitted EMI signals) of the first electromagnetic sensitive component 54 and/or the second electromagnetic sensitive component 56.

The first bump 78, the second bump 80, and the auxiliary trace 82 may form a vertical conductive loop with the shield layer 76. For example, the auxiliary trace 82 may be disposed horizontally perpendicular to (e.g., nearly horizontally perpendicular to) and in between the electromagnetic sensitive components 54 and 56. In some embodiments, the auxiliary trace 82 may be coupled to the ground traces 58. For example, the auxiliary trace 82 may be grounded (e.g., virtually grounded). Moreover, the bumps 78 and 80 may couple the sides (e.g., ends) of the auxiliary trace 82 on the first circuit layer 52 to the shield layer 76 disposed on the second circuit layer 84. As such, the auxiliary trace 82 and the bumps 78 and 80 may form a vertical conductive loop through the shield layer 76.

The vertical conductive loop may be formed on a vertical plane (e.g., nearly vertical plane) across the auxiliary trace 82 and the bumps 78 and 80. The vertical conductive loop may generate magnetic fields in opposite (e.g., nearly opposite) direction of the EMI signals passing through. In some cases, the magnetic fields may attenuate (e.g., lower an amplitude of) the EMI signals between the electromagnetic sensitive components 54 and 56. As such, the vertical conductive loop may attenuate the EMI signals between the electromagnetic sensitive components 54 and 56.

In some embodiments, the EMI shields 70 of the circuitry 50 may include the first guard ring 72 and the second guard ring 74. The guard rings 72 and 74 may each include a closed-loop conductor (e.g., trace) having a circular and/or polygonal shape. The first guard ring 72 may be disposed around and in proximity of a perimeter of the first electromagnetic sensitive component 54 on the first horizontal plane. Moreover, the second guard ring 74 may be disposed around and in proximity of a perimeter of the second electromagnetic sensitive component 56 on the first horizontal plane.

The first guard ring 72 and/or the second guard ring 74 may have overlapping boundaries or non-overlapping boundaries with the ground traces 58 disposed around the electromagnetic sensitive components 54 and 56. In some cases, the first guard ring 72 and/or the second guard ring 74 may be grounded (e.g., virtually grounded). The first guard ring 72 may attenuate (e.g., absorb at least a portion of) horizontally emitted EMI signals of the first electromagnetic sensitive component 54. The second guard ring 74 may attenuate (e.g., absorb at least a portion of) horizontally emitted EMI signals of the second electromagnetic sensitive component 56.

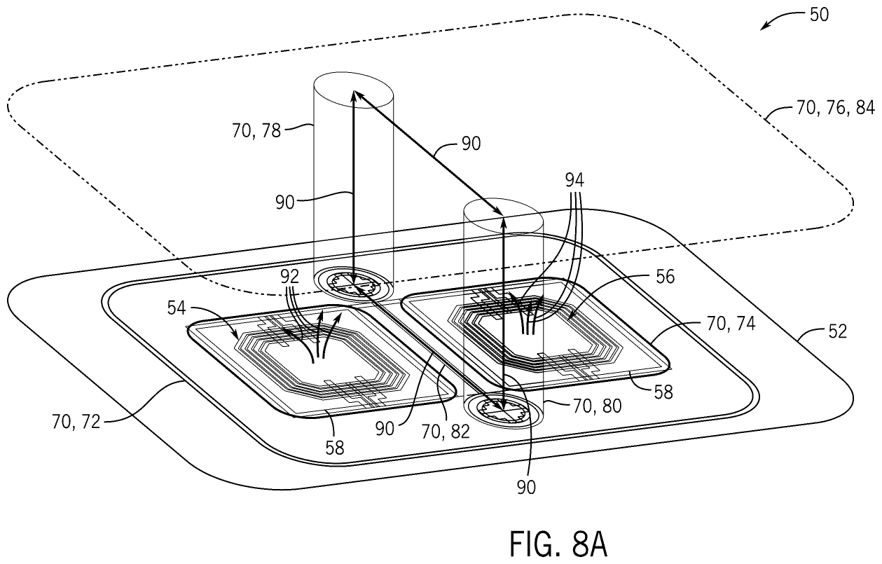

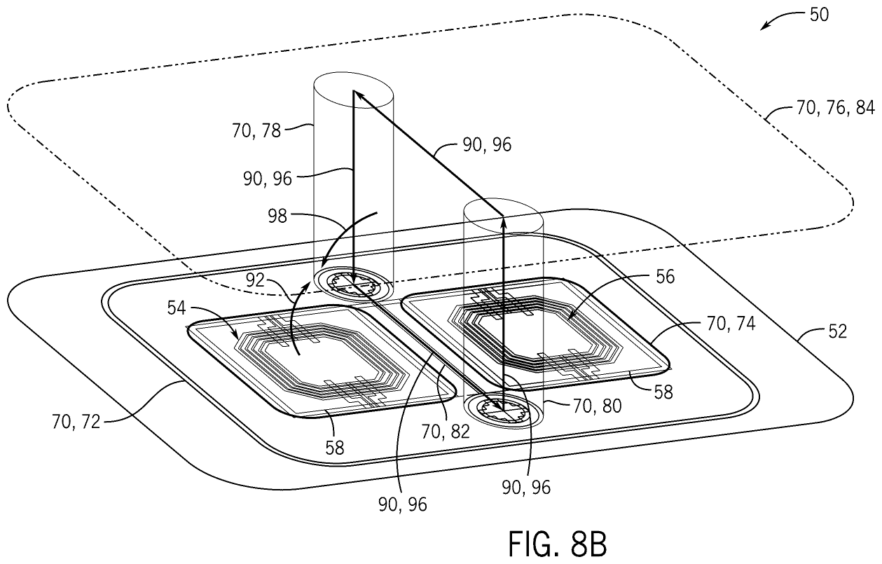

FIG. 8A is a perspective view of the layout of the circuitry 50 of FIG. 7 illustrating a vertical conductive loop 90 formed by the EMI shields 70, according to embodiments of the present disclosure. The first bump 78, the second bump 80, and the auxiliary trace 82 may form the vertical conductive loop 90 with the shield layer 76. That is, the EMI shields 70 may include the vertical conductive loop 90 formed on a vertical plane (e.g., nearly vertical plane) across the auxiliary trace 82 and the bumps 78 and 80.

For example, the first electromagnetic sensitive component 54 emits EMI signals 92 in one or multiple directions during an operation of the circuitry 50 of the electronic device 10. Moreover, the second electromagnetic sensitive component 56 emits EMI signals 94 in one or multiple directions during an operation of the circuitry 50 of the electronic device 10. In some cases, at east a portion of the EMI signals 92 and/or 94 may pass through an area of the vertical conductive loop 90. The vertical conductive loop 90 may generate magnetic fields in opposite (e.g., nearly opposite) direction of the EMI signals 92 and/or 94 passing through. In some cases, the magnetic fields may attenuate (e.g., lower an amplitude of) the EMI signals 92 and/or 94 between the electromagnetic sensitive components 54 and 56. As such, the vertical conductive loop 90 may attenuate the EMI signals 92 and/or 94 between the electromagnetic sensitive components 54 and 56.

FIG. 8B is a perspective view of the layout of the circuitry 50 of FIG. 8A illustrating induced currents 96 on the vertical conductive loop 90 generating magnetic fields 98 that attenuate undesired electromagnetic emissions (e.g., at least a portion of the EMI signals 92), according to embodiments of the present disclosure. As mentioned above, in some cases, at least a portion of the EMI signals 92 and/or 94 may pass through an area of the vertical conductive loop 90. In the depicted embodiment, the first electromagnetic sensitive component 54 emits at least a portion of the EMI signals 92 passing through an area of the vertical conductive loop 90.

The EMI signals 92 may induce the current flow 96 (e.g., induced current, eddy currents) on the vertical conductive loop 90. The induced currents 96 may generate a magnetic field 98 in opposite (e.g., nearly opposite) direction of the EMI signals 92. Moreover, the magnetic field 98 of the vertical conductive loop 90 may lower an amplitude of (e.g., attenuate) the EMI signals 92 passing through the vertical conductive loop 90. As such, the vertical conductive loop 90 may reduce an EMI (e.g., aggression) of the first electromagnetic sensitive component 54 on the second electromagnetic sensitive component 56.

In alternative or additional embodiments, the second electromagnetic sensitive component 56 may emit at least a portion of the EMI signals 94 (shown in FIG. 8A) passing through the area of the vertical conductive loop 90. In such embodiment, the EMI signals 94 may induce a current flow (e.g., the current flow 96) on the vertical conductive loop 90 generating a magnetic field in opposite (e.g., nearly opposite) direction of the EMI signals 94. As such, the vertical conductive loop 90 may reduce an EMI (e.g., aggression) of the second electromagnetic sensitive component 56 on the first electromagnetic sensitive component 54.

The vertical conductive loop 90 may improve EMI shielding (e.g., isolation) and reduce undesired interference and/or interactions between the electromagnetic sensitive components 54 and 56. That is, the EMI shields 70 may reduce undesired interference and/or interactions between the electromagnetic sensitive components 54 and 56 based on including the auxiliary trace 82 and the bumps 78 and 80 forming the vertical conductive loop 90 with the shield layer 76. In some embodiments, the electromagnetic sensitive components 54 and 56 may be disposed in a closer proximity (e.g., with a reduced distance) on the first horizontal plane of the circuitry 50 based on such improved EMI shielding. As such, the circuitry 50 including the electromagnetic sensitive components 54 and 56 may occupy a reduced area and/or have an improved EMI shielding. Accordingly, components, chips, ICs, ASICs, SoCs, and so on including the circuitry 50 may occupy a reduced area and/or have an improved EMI shielding.

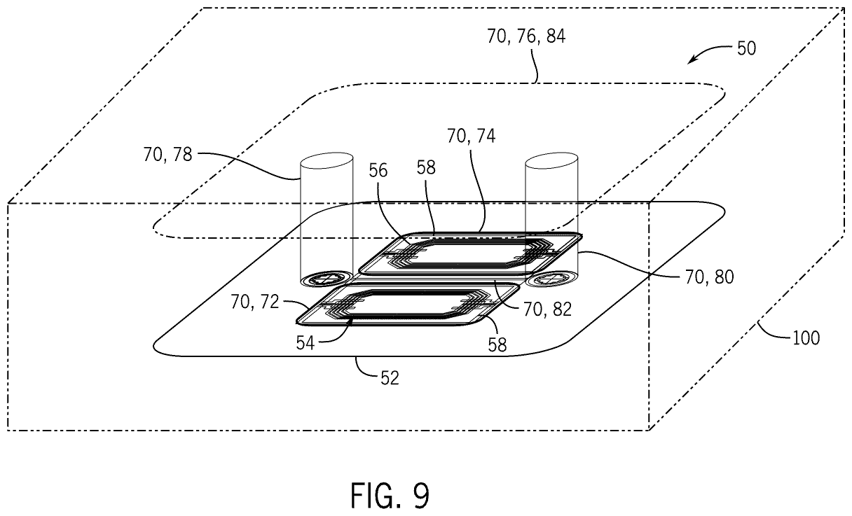

FIG. 9 is a block diagram of a package 100 including the circuitry 50 of FIGS. 6-8, according to embodiments of the present disclosure. The package 100 may include the first circuit layer 52 and the second circuit layer 84 of the circuitry 50. As mentioned above, the first circuit layer 52 and the second circuit layer 84 may each correspond to one or multiple respective layers of a printed circuit board on which the circuitry 50 is disposed. Moreover, the second circuit layer 84 may be disposed on a second horizontal plane in parallel (e.g., nearly in parallel) with the first circuit layer 52 disposed on the first horizontal plane. In some embodiments, the package 100 may include boundaries enclosing the circuitry 50. The package 100 may include circuitry additional to the circuitry 50.

In some embodiments, a die may include the first electromagnetic sensitive component 54, the second electromagnetic sensitive component 56, and the EMI shields 70. In alternative or additional embodiments, the first electromagnetic sensitive component 54, the second electromagnetic sensitive component 56, and/or the EMI shields 70 may be disposed on multiple die, one or multiple interposers, one or multiple chips, one or multiple ICs, one or multiple SoCs, or any combination thereof, among other possibilities. For example, the electromagnetic sensitive components 54 and 56 may be disposed on one or more die, hips, one or multiple ICs, one or multiple SoC, or any combination thereof in relative proximity of each other on the first circuit layer 52 of the package 100. Moreover, the shield layer 76 may be disposed on an interposer or any other viable component of the second circuit layer 84 of the package 100 overlaid on the first circuit layer 52. As mentioned above, the package 100 may include circuitry additional to the circuitry 50.

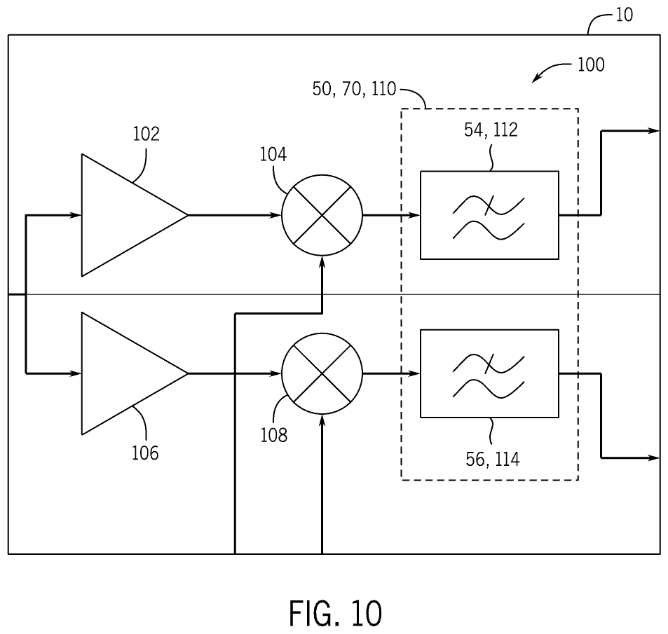

FIG. 10 is a block diagram of an example implementation of the circuitry 50 shown in FIGS. 6-9 in example filtering circuitry 110 of electronic devices 10 of FIGS. 1-5, according to embodiments of the present disclosure. In some embodiments, the electronic device 10 may include a transceiver, a transmitter, and/or a receiver, among other things, including the circuitry 50. The transceiver, the transmitter, and/or the receiver may transmit and/or receive signals within a desired frequency range. The transceiver, the transmitter, and/or the receiver may include any viable filter with the circuitry 50.

By way of example, the transceiver, the transmitter, and/or the receiver may include an in-phase and quadrature LC filters with the circuitry 50. For example, the electronic device 10 may include an in-phase amplifier 102 (e.g., a low-noise amplifier), an in-phase mixer 104, a quadrature amplifier 106, a quadrature mixer 108, and the filtering circuitry 110 including the circuitry 50 with the EMI shields 70. The in-phase amplifier 102, the in-phase mixer 104, the quadrature amplifier 106, the quadrature mixer 108, and the circuitry 50, or any combination thereof may be enclosed or packaged by the package 100 discussed above. It should be appreciated that in alternative or additional embodiments, the transceiver, the transmitter, and/or the receiver may include any other viable filter and/or have any other type of components. Moreover, it should be appreciated that the filtering circuitry 110 is one example implementation of the circuitry 50 in the electronic device 10 and the circuitry 50 may be implemented with any other viable circuitry and/or circuit component of the electronic device 10.

The in-phase amplifier 102 and the quadrature amplifier 106 may receive in-phase and quadrature components of a signal, respectively. The in-phase mixer 104 may receive an amplified in-phase signal from the in-phase amplifier 102. In some embodiments, the in-phase mixer 104 may also receive an in-phase carrier signal, for example, from an oscillator of the electronic device 10. The filtering circuitry 110 may receive an output of the in-phase mixer 104. For example, the filtering circuitry 110 and/or the circuitry 50 may include a first LC filter 112. The first LC filter 112 may include one or more capacitors coupled to the first electromagnetic sensitive component 54. The first LC filter 112 may filter the received signal to output an in-phase output signal using the first electromagnetic sensitive component 54.

Moreover, the quadrature mixer 108 may receive an amplified quadrature signal from the quadrature amplifier 106. The quadrature mixer 108 may receive a quadrature carrier signal, for example, from an oscillator of the electronic device 10. The filtering circuitry 110 may receive an output of the quadrature mixer 108. For example, the filtering circuitry 110 and/or the circuitry 50 may include a second LC filter 114. The first LC filter 112 and/or the second LC filter 114 may each include a band-pass filter, a band-stop filter (e.g., a notch filter), a high-pass filter, or a low-pass filter. The second LC filter 114 may include one or more capacitors coupled to the second electromagnetic sensitive component 56. The second LC filter 114 may filter the received signal to output a quadrature output signal using the second electromagnetic sensitive component 56.

The EMI shields 70 may reduce undesired interference and/or interactions between the electromagnetic sensitive components 54 and 56. As discussed above, the EMI shields 70 may include the auxiliary trace 82 and the bumps 78 and 80 forming the vertical conductive loop 90 with the shield layer 76. Moreover, the vertical conductive loop 90 may improve EMI shielding (e.g., isolation) and reduce undesired interference and/or interactions between the electromagnetic sensitive components 54 and 56. In some embodiments, the electromagnetic sensitive components 54 and 56 may be disposed in a closer proximity (e.g., with a reduced distance) based on such improved EMI shielding. As such, the electronic device 10, the circuitry 50, and/or the package 100 including the electromagnetic sensitive components 54 and 56 may occupy a reduced area and/or have an improved EMI shielding. Accordingly, the transceiver, the transmitter, and/or the receiver of FIG. 10 including the circuitry 50 may occupy a reduced area and/or have an improved EMI shielding compared to other transceivers, transmitters, and/or receivers.

The specific embodiments described above have been shown by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ,” it is intended that such elements are to be interpreted under 35 U.S.C. 112(f). However, for any claims containing elements designated in any other manner, it is intended that such elements are not to be interpreted under 35 U.S.C. 112(f).

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

What is claimed is:

1. An electronic device comprising:
a first component disposed on a first circuit layer;
a second component disposed on the first circuit layer;
an auxiliary trace disposed between the first component and the second component on the first circuit layer;
a first bump coupled to an end of the auxiliary trace on the first circuit layer and coupled to a shield layer on a second circuit layer;
a second bump coupled to another end of the auxiliary trace on the first circuit layer and coupled to the shield layer on the second circuit layer; and
the shield layer overlaid on the first component, the second component, the auxiliary trace, the first bump, and the second bump on the second circuit layer.

2. The electronic device of claim 1, comprising a first enclosed guard ring disposed around the first component or the second component.

3. The electronic device of claim 1, wherein the auxiliary trace is horizontally perpendicular to the first component and the second component on the first circuit layer.

4. The electronic device of claim 1, wherein the first circuit layer is disposed on a first horizontal plane and the second circuit layer is disposed on a second horizontal plane.

5. The electronic device of claim 1, wherein the shield layer comprises conductive material receiving at least a portion of electromagnetic emissions of the first component or the second component.

6. The electronic device of claim 1, wherein the auxiliary trace, the first bump, and the second bump form a conductive loop with the shield layer.

7. The electronic device of claim 6, wherein the auxiliary trace, the first bump, and the second bump attenuate at least a portion of electromagnetic emissions of the first component or the second component based on forming the conductive loop with the shield layer.

8. The electronic device of claim 6, wherein the conductive loop generates electromagnetic fields in an opposite direction of at least a portion of electromagnetic emissions of the first component or the second component.

9. The electronic device of claim 1, wherein the first component comprises an inductor.

10. A package comprising:
a first component disposed on a first circuit layer;
an auxiliary trace disposed on the first circuit layer;
a first bump coupled to an end of the auxiliary trace on the first circuit layer and coupled to a shield layer on a second circuit layer;
a second bump coupled to another end of the auxiliary trace on the first circuit layer and coupled to the shield layer on the second circuit layer; and
the shield layer overlaid on the first component, the auxiliary trace, the first bump, and the second bump on the second circuit layer.

11. The package of claim 10, comprising a second component disposed on the first circuit layer, wherein the auxiliary trace is disposed in between the first component and the second component on the first circuit layer.

12. The package of claim 11, wherein the shield layer overlaid on the first component, the second component, the auxiliary trace, the first bump, and the second bump on the second circuit layer.

13. The package of claim 10, wherein the auxiliary trace, the first bump, and the second bump form a conductive loop with the shield layer.

14. The package of claim 13, wherein the conductive loop generates electromagnetic fields in an opposite direction of at least a portion of electromagnetic emissions of the first component.

15. Filtering circuitry comprising:
one or more capacitors;
a first inductor coupled to the one or more capacitors, wherein the first inductor is disposed on a first circuit layer;
an auxiliary trace disposed on the first circuit layer;
a first bump coupled to an end of the auxiliary trace on the first circuit layer and coupled to a shield layer on a second circuit layer; and
a second bump coupled to another end of the auxiliary trace on the first circuit layer and coupled to the shield layer on the second circuit layer, wherein the auxiliary trace, the first bump, and the second bump form an enclosed conductive loop with the shield layer.

16. The filtering circuitry of claim 15, wherein the enclosed conductive loop generates electromagnetic fields in an opposite direction of at least a portion of electromagnetic emissions of the first inductor.

17. The filtering circuitry of claim 15, comprising an enclosed guard ring disposed around the first inductor.

18. The filtering circuitry of claim 15, comprising a second inductor disposed on the first circuit layer.

19. The filtering circuitry of claim 18, wherein the enclosed conductive loop generates electromagnetic fields in an opposite direction of at least a portion of electromagnetic emissions of the second inductor.

20. The filtering circuitry of claim 15, wherein the first circuit layer is disposed on a first horizontal plane and the second circuit layer is disposed on a second horizontal plane.
